(19) United States
(12) Patent Application Publication
(10) Pub. No.: US 2025/0391655 A1
(43) Pub. Date: Dec. 25, 2025

(54) METHOD OF FILLING GAP AND PROCESSING SYSTEM FOR SAME

(71) Applicant: ASM IP Holding B.V., Almere (NL)

(72) Inventors: Shinya Yoshimoto, Tokyo (JP); Makoto Igarashi, Tokyo (JP); Jaewoo Jeong, Tokyo (JP); Shanrong Zou, Kawasaki-shi (JP); Senthilkumar Rajarathinam, Tokyo (JP); Omprakash Muthusamy, Tokyo (JP); Frank Wilson Amalraj, Tokyo (JP)

(21) Appl. No.: 19/240,779

(22) Filed: Jun. 17, 2025

Related U.S. Application Data
(60) Provisional application No. 63/661,978, filed on Jun. 20, 2024.

(51) Int. Cl. H01L 21/02; C23C 16/04; C23C 16/34

(52) U.S. Cl. CPC H01L 21/0228; C23C 16/045; C23C 16/345; H01L 21/02211; H01L 21/02222; H01L 21/02274; H01L 21/02348

(57) ABSTRACT

A method of filling a gap or a feature is provided. The method may comprise introducing a substrate provided with a gap of a feature into a process system; executing one or more cycles, a cycle comprising a deposition step and a curing step, the deposition step comprising: providing a 1st precursor and a 2nd precursor, the 1st precursor comprising a Si-containing precursor; providing a process gas, wherein the process gas comprises at least one of Ar, H2, N2, He, O2, NH3, or a combination thereof and; generating a plasma, wherein the plasma causes the precursors and the process gas to react to form a gap filling fluid; the curing step comprising: simultaneously exposing the substrate to a vacuum ultraviolet radiation and to an ambient gas, thereby curing the gap filling fluid and forming a film in the gap or the feature.

### CROSS-REFERENCE TO RELATED APPLICATIONS

This application claims priority to U.S. Provisional Patent Application Ser. No. 63/661,978 filed Jun. 20, 2024 titled METHOD OF FILLING GAP AND PROCESSING SYSTEM FOR SAME, the disclosure of which is hereby incorporated by reference in its entirety.

### FIELD OF INVENTION

The present disclosure generally relates to a method of filling a gap and a processing system for the same.

### BACKGROUND OF THE DISCLOSURE

Integrated circuits are typically manufactured by an elaborate process in which various layers of materials are sequentially constructed in a predetermined arrangement on a semiconductor substrate.

Some embodiments herein relate to semiconductor fabrication, and methods and apparatuses for flowable deposition of thin films. In semiconductor fabrication, it is often necessary to fill gaps in a substrate, for example with insulating material. As device geometries shrink, void-free filling of gaps becomes increasingly difficult due to limitations of existing deposition processes. The films typically deposited by existing flowable gap-fill processes have a variety of drawbacks. For example, they may exhibit poor quality and/or bad thermal stability.

Flowable SiCN and SiOCN films are used in various applications. There is a need to change an atomic composition in the flowable SiCN and SiOCN films to improve the film quality.

Any discussion, including discussion of problems and solutions, set forth in this section, has been included in this disclosure solely for the purpose of providing a context for the present disclosure, and should not be taken as an admission that any or all of the discussion was known at the time the invention was made or otherwise constitutes prior art.

### SUMMARY OF THE DISCLOSURE

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

In accordance with exemplary embodiments of the disclosure, a method of filling a gap or a feature is provided. The method may comprise introducing a substrate provided with a gap of a feature into a process system; executing one or more cycles, a cycle comprising a deposition step and a curing step, the deposition step comprising: providing a 1st precursor and a 2nd precursor, the 1st precursor comprising a Si-containing precursor; providing a process gas, wherein the process gas comprises at least one of Ar, H2, N2, He, O2, NH3, or a combination thereof and; generating a plasma, wherein the plasma causes the precursors and the process gas to react to form a gap filling fluid; the curing step comprising: simultaneously exposing the substrate to a vacuum ultraviolet radiation and to an ambient gas, thereby curing the gap filling fluid and forming a film in the gap or the feature.

In accordance with further exemplary embodiments of the disclosure, the 1st precursor may comprise at least one of hexamethyldisilazane, 1,1,3,3-tetramethyl-1,3-divinyldisilazane, N′-[(disilylamino)silyl]-N,N-disilylsilanediamine, 1,1,3,3-tetramethyldisilazane, 1,3-divinyl-1,1,3,3-tetramethyldisilazane, heptamethyldisilazane, or N,N′-disilylsilanediamine.

In accordance with further exemplary embodiments of the disclosure, the 2nd precursor may comprise at least one of tetrasilyl-silanediamine, Tetraethyl orthosilicate, Methoxysilane (Tetramethoxysilane), Methoxysiloxane (hexamethoxydisiloxane), Methoxysilylmethane (bis(trimethoxysilyl) methane), benzene; indene; cyclopentadiene; cyclohexane; pyrrole; furan; thiophene; phosphole; pyrazole; imidazole; oxazole; isoxazole; thiazole; indole; benzofuran; benzothiophene; isoindole; isobenzofuran; benzophosphole; benzimidazole; benzoxazole; benzothiazole; benzoisoxazole; indazole; benzoisothiazole; benzotriazole; purine; pyridine; phosphinine; pyrimidine; pyrazine; pyridazine; triazine; 1,2,4,5-tetrazine; 1,2,3,4-tetrazine; 1,2,3,5-tetrazine; hexazine, quinoline; isoquinoline; quinoxaline; quinazoline; cinnoline; pteridine; phthalazine; acridine; 4aH-xanthene; 4aH-thioxanthene; 4aH-phenoxazine; 4a, 10a-dihydro-10H-phenothiazine; or carbazole.

In accordance with further exemplary embodiments of the disclosure, the 2nd precursor may be intermittently provided in the form of pulses.

In accordance with further exemplary embodiments of the disclosure, the ambient gas may comprise at least one of N2, H2, Ar, He, or combination thereof.

In accordance with further exemplary embodiments of the disclosure, the ambient gas may comprise NH3.

In accordance with further exemplary embodiments of the disclosure, the film may comprise at least one of a SiCN, SiCO, SiON, or SiCON.

In accordance with further exemplary embodiments of the disclosure, the deposition step and the curing step may be carried out in the same process system, without any intervening vacuum break.

In accordance with further exemplary embodiments of the disclosure, the vacuum ultraviolet radiation may comprise electromagnetic radiation with a wavelength of at least 150 nm to at most 200 nm.

In accordance with further exemplary embodiments of the disclosure, the deposition step may be carried out in a first reaction chamber, wherein the curing step may be carried out in a second reaction chamber, and wherein the first reaction chamber and the second reaction chamber may be different reaction chambers comprised in the same process system.

In accordance with further exemplary embodiments of the disclosure, the deposition step may be carried out at a deposition temperature, which is between 50° C. and 300° C.

In accordance with further exemplary embodiments of the disclosure the curing step may be carried out at a curing temperature which is between the deposition temperature and 600°.

In accordance with further exemplary embodiments of the disclosure, the method may further comprise a step of plasma-curing, wherein the plasma-curing comprising exposing the substrate to reactive species generated by a plasma from at least one of He, H2 or Ar.

In accordance with further exemplary embodiments of the disclosure, the method may further comprise a step of annealing the substrate at an annealing temperature, the annealing temperature being higher than a deposition temperature.

In accordance with further exemplary embodiments of the disclosure, a processing system is provided. The processing system may comprise a first reaction chamber; a 1st precursor source; a 2nd precursor source; a 1st precursor line; a 2nd precursor line; and a vacuum ultraviolet light source; wherein the 1st precursor source comprises a 1st precursor, the 1st precursor comprising a Si-containing precursor; wherein the 1st precursor line is configured to provide the 1st precursor from the 1st precursor source to the first reaction chamber; wherein the 2nd precursor line is configured to provide the 2nd precursor from the 2nd precursor source to the first reaction chamber; and wherein the vacuum ultraviolet light source is configured to generate a vacuum ultraviolet light.

In accordance with further exemplary embodiments of the disclosure, the processing system may further comprise a second reaction chamber, and a wafer handling system, the vacuum ultraviolet light source being arranged for providing vacuum ultraviolet light to the second reaction chamber, the wafer handling system being arranged for transporting one or more wafers between the first reaction chamber and the second reaction chamber.

In accordance with further exemplary embodiments of the disclosure, the processing system may further comprise a controller, the controller being arranged for causing the processing system to carry out a method comprising: introducing in the first reaction chamber a substrate provided with a gap, the gap comprising a gap filling fluid; and simultaneously exposing the substrate to vacuum ultraviolet radiation and to an ambient gas; thereby curing the gap filling fluid and forming a film in the gap.

### BRIEF DESCRIPTION OF THE DRAWING FIGURES

A more complete understanding of exemplary embodiments of the present disclosure can be derived by referring to the detailed description and claims when considered in connection with the following illustrative figures.

FIG. 1 illustrates a method in accordance with exemplary embodiments of the disclosure.

FIG. 2 illustrates a XPS composition result in accordance with exemplary embodiments of the disclosure.

FIG. 3 illustrates a timing sequence in accordance with exemplary embodiments of the disclosure.

FIG. 4 illustrates a timing sequence in accordance with exemplary embodiments of the disclosure.

FIG. 5 illustrates a schematic view of a quad chamber module with deposition chambers in accordance with exemplary embodiments of the disclosure.

FIG. 6 illustrates a multi-process chamber module and process in accordance with exemplary embodiments of the disclosure.

FIG. 7 illustrates a cyclic process in accordance with exemplary embodiments of the disclosure.

FIG. 8 illustrates a cyclic process in accordance with exemplary embodiments of the disclosure.

FIG. 9 illustrates a plasma apparatus in accordance with exemplary embodiments of the disclosure.

It will be appreciated that elements in the figures are illustrated for simplicity and clarity and have not necessarily been drawn to scale. For example, the dimensions of some of the elements in the figures may be exaggerated relative to other elements to help understanding of illustrated embodiments of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below.

As used herein, the term “substrate” may refer to any underlying material or materials, including any underlying material or materials that may be modified, or upon which, a device, a circuit, or a film may be formed. The “substrate” may be continuous or non-continuous; rigid or flexible; solid or porous; and combinations thereof. The substrate may be in any form, such as a powder, a plate, or a workpiece. Substrates in the form of a plate may include wafers in various shapes and sizes. Substrates may be made from semiconductor materials, including, for example, silicon, silicon germanium, silicon oxide, gallium arsenide, gallium nitride and silicon carbide.

As examples, a substrate in the form of a powder may have applications for pharmaceutical manufacturing. A porous substrate may comprise polymers. Examples of workpieces may include medical devices (for example, stents and syringes), jewelry, tooling devices, components for battery manufacturing (for example, anodes, cathodes, or separators) or components of photovoltaic cells, etc.

A continuous substrate may extend beyond the bounds of a process chamber where a deposition process occurs. In some processes, the continuous substrate may move through the process chamber such that the process continues until the end of the substrate is reached. A continuous substrate may be supplied from a continuous substrate feeding system to allow for manufacture and output of the continuous substrate in any appropriate form.

Non-limiting examples of a continuous substrate may include a sheet, a non-woven film, a roll, a foil, a web, a flexible material, a bundle of continuous filaments or fibers (for example, ceramic fibers or polymer fibers). Continuous substrates may also comprise carriers or sheets upon which non-continuous substrates are mounted.

The illustrations presented herein are not meant to be actual views of any particular material, structure, or device, but are merely idealized representations that are used to describe embodiments of the disclosure.

The particular implementations shown and described are illustrative of the invention and its best mode and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationship or physical connections may be present in the practical system, and/or may be absent in some embodiments.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject matter of the present disclosure includes all novel and nonobvious combinations and subcombinations of the various processes, systems, and configurations, and other features, functions, acts, and/or properties disclosed herein, as well as any and all equivalents thereof.

In this disclosure, “gas” may include material that is a gas at normal temperature and pressure, a vaporized solid and/or a vaporized liquid, and may be constituted by a single gas or a mixture of gases, depending on the context. A gas introduced without passing through a gas supply unit, such as a shower plate, or the like, may be used for, e.g., sealing the reaction space, and may include a seal gas, such as a rare or other inert gas. The term inert gas, carrier gas, and dilution gas refer to a gas that does not take part in a chemical reaction to an appreciable extent and/or a gas that can excite a precursor when plasma power is applied.

As used herein, the term “film” and “thin film” may refer to any continuous or non-continuous structures and material deposited by the methods disclosed herein. For example, “film” and “thin film” could include 2D materials, nanorods, nanotubes, or nanoparticles or even partial or full molecular layers or partial or full atomic layers or clusters of atoms and/or molecules. “Film” and “thin film” may comprise material or a layer with pinholes, but still be at least partially continuous.

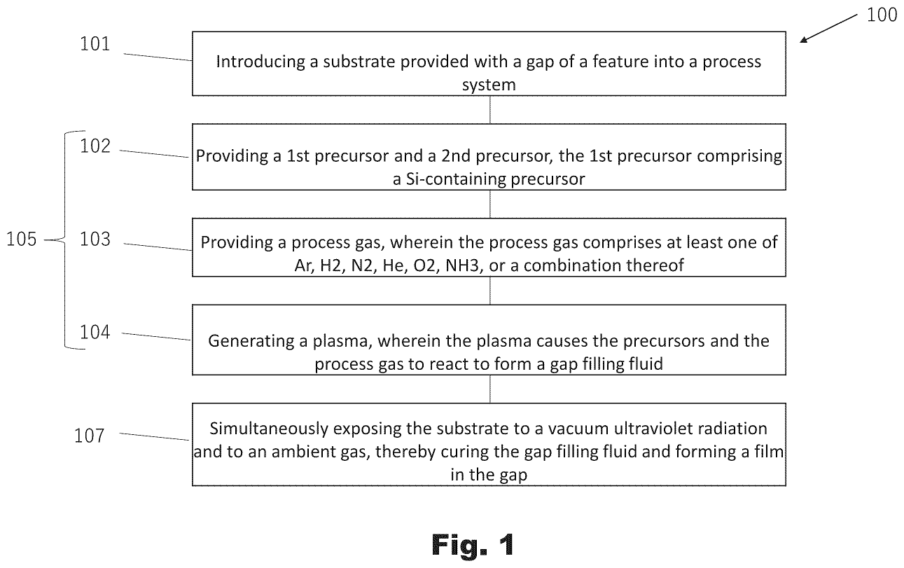

FIG. 1 illustrates a method 100 of filling a gap or a feature with exemplary embodiments of the disclosure. Method 100 includes a step of introducing a substrate provided with a gap or a feature into a process system (step 101) and executing one or more cycles, a cycle comprising a flowable deposition step (step 105) and a curing step (step 107).

The flowable deposition step 105 may comprise providing a 1st precursor and a 2nd precursor (step 102); providing a process gas (step 103); and generating a plasma (step 104). The plasma may cause the precursors and the process gas to react to form a gap filling fluid.

The curing step 107 may comprise simultaneously exposing the substrate to a vacuum ultraviolet (VUV) radiation and to an ambient gas, thereby curing the gap filling fluid and forming a film in the gap or the future.

During the step 101, the substrate can be brought to a desired temperature and the processing system can be brought to a desired pressure, such as a temperature and pressure suitable for the flowable deposition step. By way of examples, a temperature (e.g., of a substrate or a substrate support) within a reaction chamber can be between 50° C. and 300° C. In accordance with particular examples of the disclosure, the substrate includes one or more features, such as gaps.

During the step 102, the 1st precursor and 2nd precursor may be provided. The 1st precursor may comprise at least one of hexamethyldisilazane, 1,1,3,3-tetramethyl-1,3-divinyldisilazane, N′-[(disilylamino)silyl]-N,N-disilylsilanediamine, 1,1,3,3-tetramethyldisilazane, 1,3-divinyl-1,1,3,3-tetramethyldisilazane, heptamethyldisilazane, or N,N′-disilylsilanediamine. The 1st precursor may comprise a silicon-containing precursor.

The 2nd precursor may comprise at least one of tetrasilyl-silanediamine, Tetraethyl orthosilicate, Methoxysilane (Tetramethoxysilane), Methoxysiloxane (hexamethoxydisiloxane), Methoxysilylmethane (bis(trimethoxysilyl) methane), benzene; indene; cyclopentadiene; cyclohexane; pyrrole; furan; thiophene; phosphole; pyrazole; imidazole; oxazole; isoxazole; thiazole; indole; benzofuran; benzothiophene; isoindole; isobenzofuran; benzophosphole; benzimidazole; benzoxazole; benzothiazole; benzoisoxazole; indazole; benzoisothiazole; benzotriazole; purine; pyridine; phosphinine; pyrimidine; pyrazine; pyridazine; triazine; 1,2,4,5-tetrazine; 1,2,3,4-tetrazine; 1,2,3,5-tetrazine; hexazine, quinoline; isoquinoline; quinoxaline; quinazoline; cinnoline; pteridine; phthalazine; acridine; 4aH-xanthene; 4aH-thioxanthene; 4aH-phenoxazine; 4a, 10a-dihydro-10H-phenothiazine; or carbazole.

During the step 103, the process gas may be provided. The process gas may comprise at least one of Ar, H2, N2, He, O2, NH3, or a combination thereof.

During the step 104, the plasma may be generated using a direct plasma system by a radio frequency (RF) plasma source 108 including a high frequency (HF) component. By the providing the plasma, the precursor reacts with the reactant to form a layer. The high frequency (HF) may have a frequency in a range between about 13 MHz and about 27 MHz. The high frequency RF power may be between about 30 watts and about 500 watts. The low frequency may be further added. The low frequency (LF) power may have a frequency in a range between about 100 KHz and about 500 KHz.

During the curing step 107, the substrate may be exposed to a vacuum ultraviolet (VUV) radiation and to an ambient gas, thereby curing the gap filling fluid and forming a film in the gap or the feature. The film may comprise at least one of a SiCN, SiCO, SiON, or SiCON.

The ambient gas may comprise at least one of N2, H2, Ar, He, or combination thereof. In at least one embodiment, the ambient gas may comprise NH3. By using NH3, the Nitrogen composition in SiCN film may be tuned.

The vacuum ultraviolet radiation may comprise electromagnetic radiation with a wavelength of at least 150 nm to at most 200 nm.

The curing step may be carried out at a curing temperature, which is greater than the deposition temperature. The curing temperature may also be less than 600° C.

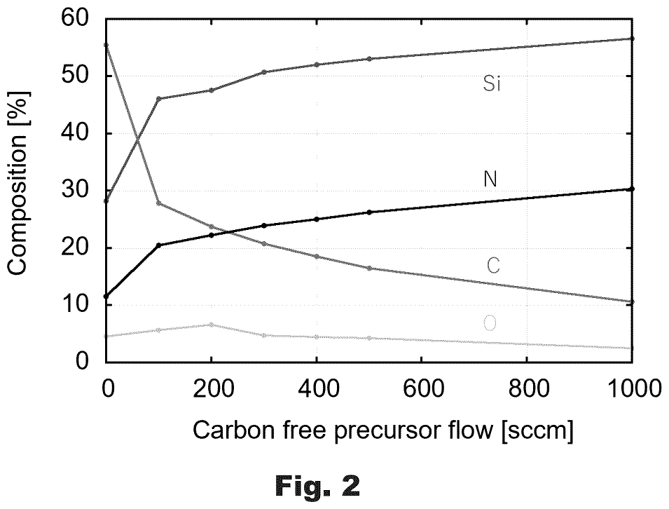

FIG. 2 illustrates a XPS composition result in accordance with exemplary embodiments of the disclosure. By using a carbon-free precursor as the 2nd precursor and changing the flow rate during deposition, the carbon composition can be turned while keeping a flowability. In this example, by using hexamethyldisilazane as the 1st precursor and tetrasilyl-silanediamine as the 2nd precursor, the carbon composition can be tuned between 55% and 10%. Alternatively, by using a carbon containing precursor as the 2nd precursor and changing the flow rate during deposition, the carbon composition can be also turned.

Further, by using an oxygen containing precursor as the 2nd precursor (e.g. Tetraethyl orthosilicate) and changing the flow rate during deposition, the oxygen composition can be turned and SiCO, SiON, or SiCON can be formed.

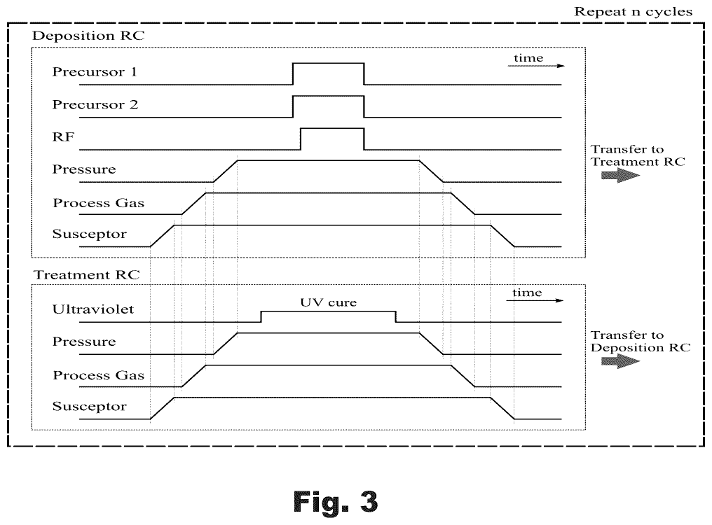

FIG. 3 illustrates a timing sequence in accordance with exemplary embodiments of the disclosure. A duration of the 1st precursor (precursor 1) feed may be between 2 and 600 seconds. A duration of the 2nd precursor (precursor 2) feed may be between 2 and 600 seconds. A duration of the RF generation may be between 1 and 600 seconds. Further, a duration of the VUV curing in the curing (treatment) step may be between 30 and 900 seconds.

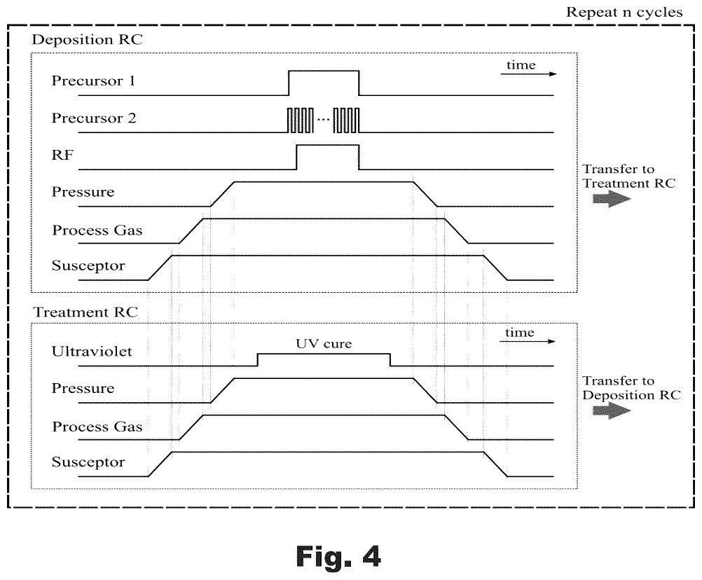

FIG. 4 illustrates another timing sequence in accordance with exemplary embodiments of the disclosure. In order to control the composition, the 2nd precursor may be intermittently provided in the form of pulses. The pulsing speed may be 1-10 Hz with duty ratio of 5%-95% to obtain a uniform film.

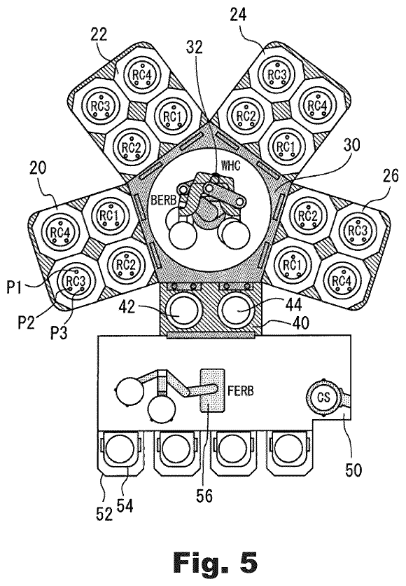

FIG. 5 is a schematic plan view of a substrate processing apparatus with quad chamber modules in an embodiment of the present invention. The substrate processing apparatus may comprise: (i) four process modules 20, 22, 24, 26, each having four reaction chambers RC1, RC2, RC3, RC4; (ii) a substrate handling chamber 30 including two back end robots 32 (substrate handling robots); and (iii) a load lock chamber 40 for loading or unloading two substrates simultaneously, the load lock chamber 40 being attached to the one additional side of the substrate handling chamber 30, wherein each back end robot 32 is accessible to the load lock chamber 40. Each of the back end robots 32 may have at least two end-effectors accessible to the two reaction chambers of each unit simultaneously, said substrate handling chamber 30 having a polygonal shape having four sides corresponding to and being attached to the four process modules 20, 22, 24, 26, respectively, and one additional side for a load lock chamber 40, all the sides being disposed on the same plane. The interior of each process modules 20, 22, 24, 26 and the interior of the load lock chamber 40 may be isolated from the interior of the substrate handling chamber 30 by at least one gate valve.

In some embodiments, a controller (not shown) may store software programmed to execute sequences of substrate transfer, for example. The controller may also: check the status of each process chamber; position substrates in each process chamber using sensing systems; control a gas box; control an electric box for each module; control a front end robot 56 in an equipment front end module based on a distribution status of substrates stored in FOUP 52 and the load lock chamber 40; control the back end robots 32; and control the control gate valves and other valves.

A skilled artisan may appreciate that the apparatus may include one or more controller(s) programmed or otherwise configured to cause the anneal and deposition processes described elsewhere herein to be conducted. The controller(s) may communicate with the various power sources, heating systems, pumps, robotics, gas flow controllers, or valves, as will be appreciated by the skilled artisan.

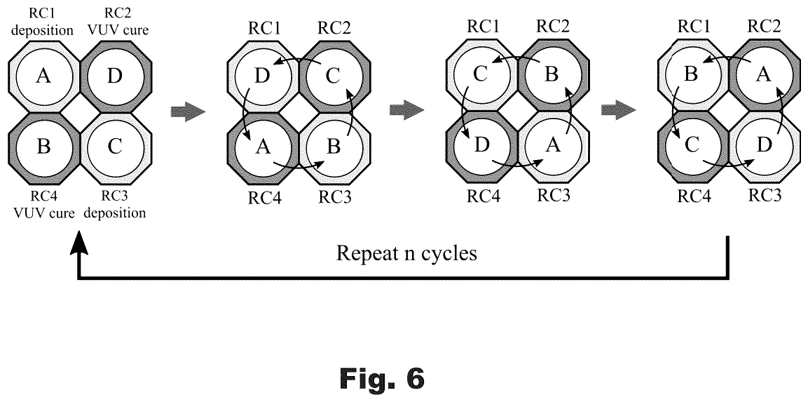

As illustrated in FIG. 6, a substrate may enter the chamber at RC1, at which the substrate may undergo a first flowable deposition process. In some embodiments, after undergoing the first flowable deposition process, the substrate may be transferred to RC4. Alternatively, the substrate may be transferred to RC2. In either case, the substrate may undergo a first treatment process, which may include thermal annealing, VUV curing, or both. After the first treatment process, the substrate may be transferred to RC3, where it may undergo a second flowable deposition process that may be similar to or the same as the first flowable deposition process. After undergoing the second flowable deposition process, the substrate may be transferred to RC2 if it was previously transferred to RC4 or may be transferred to RC4 if it was previously transferred to RC2. In either case, the substrate may undergo a second treatment process that is similar to or the same as the first treatment process. The substrate may be transferred back to RC1 to complete a single deposition-treatment cycle.

The cycle may be repeated to achieve desired film quality and thickness. Furthermore, the substrate may enter the chamber at any one of RC1, RC2, RC3, or RC4 and cycle through the stations in any direction. Generally, however, the deposition-treatment cycle will begin with at least one flowable deposition process followed by at least one treatment process. The at least one flowable deposition process may be performed simultaneously on different substrates and/or performed sequentially on a single substrate.

In the illustrated embodiment of FIG. 6, deposition stations and treatment stations of the same type are positioned diagonally. In some embodiments, this configuration may improve film uniformity. In some embodiments, two or more pairs of reactions chambers perform the same process on two or more substrates in parallel.

The above cyclic concept can also be applied to different numbers of reaction chambers. In some embodiments, a multi-process chamber module as described herein can comprise multiple stations, half of which may be used for flowable deposition and the other half of which may be used for treatment processes. In some embodiments, a multi-process chamber module comprises at least 2 stations, for example at least 2, 3, 4, 5, 6, 7, 8, 9, 10, 11, 12, 13, 14, 15, 16, 17, 18, 19, 20, 30, 40, 50, 100, 150, 200, 250, 300, 400, or 500 stations, including ranges between any two of the listed values. However, the number of stations is not necessarily limited.

In some embodiments, all stations may be equipped with VUV units, or half of the stations may be equipped with VUV units, or any other number of stations may be equipped with VUV units.

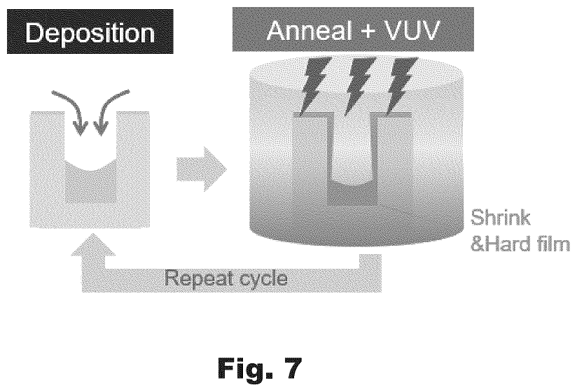

FIG. 7 illustrates an example process according to some embodiments that could be carried out on a system having one or more reaction chambers equipped with a VUV unit. A substrate may undergo a film deposition step in a first RC, then be transferred to a second RC to undergo annealing and VUV curing treatment to shrink and harden the film. The VUV treatment may be performed in the deposition station, in an annealing station (not shown), or in the annealing and VUV station. The process may be repeated until a film of desired quality and thickness is formed.

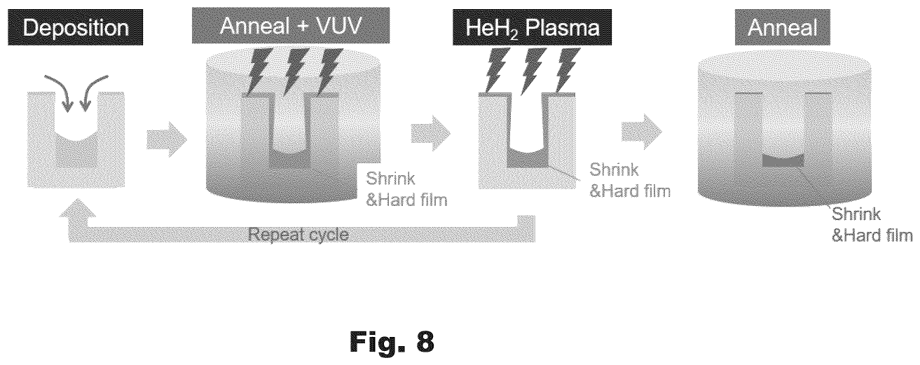

FIG. 8 illustrates an example process according to some embodiments. A substrate may undergo a film deposition step in a first RC, then be transferred to a second RC to undergo annealing and VUV curing treatment to shrink and harden the film. Then, the film may be subjected to a plasma treatment (e.g., a hydrogen, argon, or helium plasma treatment) to shrink and harden the film. Furthermore, the film may be thermally annealed to shrink and harden the film.

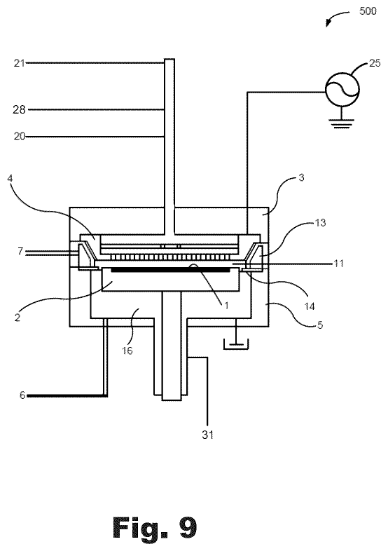

FIG. 9 illustrates a plasma reactor system 500 in accordance with exemplary embodiments of the disclosure is illustrated. The plasma reactor system 500 can be used to perform one or more steps or sub steps as described herein and/or to form one or more structures or portions thereof as described herein.

The plasma reactor system 500 may include a pair of electrically conductive flat-plate electrodes 4, 2 in parallel and facing each other in an interior 11 (reaction zone) of a reaction chamber 3. A plasma can be excited within the reaction chamber 3 by applying HF power (e.g., 13.56 MHz or 27 MHz) and/or LF power (e.g. 450k Hz) from a power source 25 to one electrode (e.g., electrode 4) and electrically grounding the other electrode (e.g., electrode 2). A temperature regulator may be provided in a lower stage 2 (the lower electrode), and a temperature of a substrate 1 placed thereon may be kept at a desired temperature. The electrode 4 may serve as a gas distribution device, such as a shower plate. Reactant gas, process gas, dilution gas, if any, precursor gas, and/or the like in may be introduced into reaction chamber 3 using one or more of a gas line 20, a gas line 21, and a gas line 28, respectively, and through the shower plate 4. Although illustrated with three gas lines, the reactor system 500 may include any suitable number of gas lines.

In the reaction chamber 3, a circular duct 13 with an exhaust line 7 may be provided, through which gas in the interior 11 of the reaction chamber 3 may be exhausted. Additionally, a transfer chamber 5, disposed below the reaction chamber 3, may be provided with a seal gas line 31 to introduce seal gas into the interior 11 of the reaction chamber 3 via the interior 16 (transfer zone) of the transfer chamber 5. A separation plate 14 for separating the reaction zone and the transfer zone may be provided. The transfer chamber may be also provided with an exhaust line 6. In some embodiments, the deposition and treatment steps may be performed in the same reaction space, so that two or more (e.g., all) of the steps can continuously be conducted without exposing the substrate to air or other oxygen-containing atmosphere.

The example embodiments of the disclosure described above do not limit the scope of the invention, since these embodiments are merely examples of the embodiments of the invention. Any equivalent embodiments are intended to be within the scope of this invention. Indeed, various modifications of the disclosure, in addition to those shown and described herein, such as alternative useful combinations of the elements described, may become apparent to those skilled in the art from the description. Such modifications and embodiments are also intended to fall within the scope of the appended claims.

What is claimed is:

1. A method of filling a gap or a feature comprising:
introducing a substrate provided with a gap of a feature into a process system; and
executing one or more cycles, a cycle comprising a deposition step and a curing step, the deposition step comprising:
providing a 1^{st} precursor and a 2^{nd} precursor, the 1^{st} precursor comprising a Si-containing precursor;
providing a process gas, wherein the process gas comprises at least one of Ar, H₂, N₂, He, O₂, NH₃, or a combination thereof; and
generating a plasma, wherein the plasma causes the precursors and the process gas to react to form a gap filling fluid;
the curing step comprising:
simultaneously exposing the substrate to a vacuum ultraviolet radiation and to an ambient gas, thereby curing the gap filling fluid and forming a film in the gap or the feature.

2. The method of claim 1, wherein the 1^{st} precursor comprises at least one of hexamethyldisilazane, 1,1,3,3-tetramethyl-1,3-divinyldisilazane, N′-[(disilylamino)silyl]-N,N-disilylsilanediamine, 1,1,3,3-tetramethyldisilazane, 1,3-divinyl-1,1,3,3-tetramethyldisilazane, heptamethyldisilazane, or N,N′-disilylsilanediamine.

3. The method of claim 1, wherein the 2^{nd} precursor comprises at least one of tetrasilyl-silanediamine, Tetraethyl orthosilicate, Methoxysilane (Tetramethoxysilane), Methoxysiloxane (hexamethoxydisiloxane), Methoxysilylmethane (bis(trimethoxysilyl) methane), benzene; indene; cyclopentadiene; cyclohexane; pyrrole; furan; thiophene; phosphole; pyrazole; imidazole; oxazole; isoxazole; thiazole; indole; benzofuran; benzothiophene; isoindole; isobenzofuran; benzophosphole; benzimidazole; benzoxazole; benzothiazole; benzoisoxazole; indazole; benzoisothiazole; benzotriazole; purine; pyridine; phosphinine; pyrimidine; pyrazine; pyridazine; triazine; 1,2,4,5-tetrazine; 1,2,3,4-tetrazine; 1,2,3,5-tetrazine; hexazine, quinoline; isoquinoline; quinoxaline; quinazoline; cinnoline; pteridine; phthalazine; acridine; 4aH-xanthene; 4aH-thioxanthene; 4aH-phenoxazine; 4a, 10a-dihydro-10H-phenothiazine; or carbazole.

4. The method of claim 1, wherein the 2^{nd} precursor is intermittently provided in the form of pulses.

5. The method of claim 1, wherein the ambient gas comprises at least one of N2, H2, Ar, He, or combination thereof.

6. The method of claim 1, wherein the ambient gas comprises NH3.

7. The method of claim 1, wherein the film comprises at least one of a SiCN, SiCO, SiON, or SiCON.

8. The method of claim 1, wherein the deposition step and the curing step are carried out in the same process system, without any intervening vacuum break.

9. The method of claim 1, wherein the vacuum ultraviolet radiation comprises electromagnetic radiation with a wavelength of at least 150 nm to at most 200 nm.

10. The method of claim 1, wherein the deposition step is carried out in a first reaction chamber, wherein the curing step is carried out in a second reaction chamber, and wherein the first reaction chamber and the second reaction chamber are different reaction chambers comprised in the same process system.

11. The method of claim 1, wherein the deposition step is carried out at a deposition temperature, which is between 50° C. and 300° C.

12. The method of claim 11, wherein the curing step is carried out at a curing temperature greater than the deposition temperature.

13. The method of claim 1, wherein the curing step is carried out at a curing temperature less than 600° C.

14. The method of claim 1, further comprising a step of plasma-curing, wherein the plasma-curing comprising exposing the substrate to reactive species generated by a plasma from at least one of He, H2 or Ar.

15. The method of claim 14, further comprising a step of annealing the substrate at an annealing temperature, the annealing temperature being higher than a deposition temperature.

16. A processing system comprising:
a first reaction chamber;
a 1^{st} precursor source;
a 2^{nd} precursor source;
a 1^{st} precursor line;
a 2^{nd} precursor line; and
a vacuum ultraviolet light source;
wherein the 1^{st} precursor source comprises a 1^{st} precursor, the 1^{st} precursor comprising a Si-containing precursor;
wherein the 1^{st} precursor line is configured to provide the 1^{st} precursor from the 1^{st} precursor source to the first reaction chamber;
wherein the 2^{nd} precursor line is configured to provide the 2^{nd} precursor from the 2^{nd} precursor source to the first reaction chamber; and
wherein the vacuum ultraviolet light source is configured to generate a vacuum ultraviolet light.

17. The processing system of claim 16, further comprising a second reaction chamber, and a wafer handling system, the vacuum ultraviolet light source being arranged for providing vacuum ultraviolet light to the second reaction chamber, the wafer handling system being arranged for transporting one or more wafers between the first reaction chamber and the second reaction chamber.

18. The processing system of claim 16, further comprising a controller, the controller being arranged for causing the processing system to carry out a method comprising:
introducing in the first reaction chamber a substrate provided with a gap, the gap comprising a gap filling fluid; and
simultaneously exposing the substrate to vacuum ultraviolet radiation and to an ambient gas;
thereby curing the gap filling fluid and forming a film in the gap.
